(19) United States
(12) Patent Application Publication
(10) Pub. No.: US 2010/0155730 A1
(43) Pub. Date: Jun. 24, 2010

(54) THIN FILM TRANSISTOR DISPLAY PANEL AND MANUFACTURING METHOD THEREOF

(75) Inventors: Sun-Young HONG, Yongin-si (KR); Young-Joo CHOI, Yongin-si (KR); Nam-Seok SUH, Yongin-si (KR); Hong-Sick PARK, Suwon-si (KR); Jong-Hyun CHOUNG, Hwaseong-si (KR); Bong-Kyun KIM, Incheon (KR); Byeong-Jin LEE, Seoul (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 12/481,158

(22) Filed: Jun. 9, 2009

(30) Foreign Application Priority Data
Dec. 24, 2008 (KR) 10-2008-0133827

(51) Int. Cl. H01L 33/00; H01L 21/336; H01L 29/786

(52) U.S. Cl. 257/59; 438/34; 438/157; 257/43; 257/72; 438/38; 257/E33.053; 257/E21.414; 257/E29.291

(57) ABSTRACT

In the manufacturing process of the thin film transistor array panel according to an exemplary embodiment of the present invention using three masks, the metal oxide semiconductor or the transparent conductive oxide is used, thereby executing an efficient lift-off process.

### CROSS REFERENCE TO RELATED APPLICATION

This application claims priority from and the benefit of Korean Patent Application No. 10-2008-0133827, filed on Dec. 24, 2008, which is hereby incorporated by reference for all purposes as if fully set forth herein.

### BACKGROUND OF THE INVENTION

1. Field of the Invention

The present invention relates to a thin film transistor array panel and a manufacturing method thereof.

2. Discussion of the Background

Flat panel displays include various types of displays such as a liquid crystal display and an organic light emitting device. Of the flat panel displays, liquid crystal displays are now widely used. Liquid crystal displays generally include two display panels on which field generating electrodes such as pixel electrodes and a common electrode are formed, and a liquid crystal layer interposed between the panels. In the liquid crystal display, voltages are applied to the field generating electrodes to generate an electric field over the liquid crystal layer. The alignment of liquid crystal molecules of the liquid crystal layer is determined by the electric field. Accordingly, polarization of incident light is controlled by the alignment of the liquid crystal molecules, thereby displaying images.

Further, the flat panel displays include display panels formed with thin film transistors. The thin film transistor array panels thus formed are patterned with multiple electrodes and semiconductors, and masks are generally used in the patterning process. However, time and cost increase when using masks such that processes to reduce the number of masks have developed to improve the productivity of thin film transistor array panels.

### SUMMARY OF THE INVENTION

Exemplary embodiments of the present invention provide a thin film transistor array panel.

Exemplary embodiments of the present invention also provide a manufacturing process of a thin film transistor array panel using three masks, a metal oxide semiconductor or a transparent conductive oxide, thereby executing an efficient lift-off process.

Additional features of the invention will be set forth in the description which follows, and in part will be apparent from the description, or may be learned by practice of the invention.

An exemplary embodiment of the present invention discloses a thin film transistor array panel, which includes a substrate and a gate line disposed on the substrate, and the gate line includes a gate electrode. A gate insulating layer is disposed on the gate line; and a semiconductor is disposed on the gate insulating layer. A data line is disposed on the semiconductor and the data line includes a source electrode. A drain electrode is disposed on the semiconductor and faces the source electrode. A passivation layer is disposed on the data line and the drain electrode. An upper layer is disposed on the passivation layer and includes a metal oxide semiconductor or a transparent conductive oxide. A pixel electrode is disposed on the upper layer and is connected to the drain electrode, wherein the upper layer includes a first upper layer pattern overlapping with the pixel electrode.

An exemplary embodiment of the present invention discloses a manufacturing method of a thin film transistor array panel including: forming a gate line including a gate electrode on a substrate; forming a gate insulating layer on the gate line; and depositing a semiconductor on the gate insulating layer. The manufacturing method also includes depositing a data line on the semiconductor; simultaneously patterning the semiconductor and the data line; depositing a passivation layer on the data line; depositing an upper layer on the passivation layer; forming a photosensitive film pattern on the upper layer; etching the upper layer by using the photosensitive film pattern as a mask; etching the passivation layer; and forming a pixel electrode on the passivation layer. The upper layer includes a metal oxide semiconductor or a transparent conductive oxide in the manufacturing method, and the upper layer includes a first upper layer pattern overlapping with the pixel electrode.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a layout view of a thin film transistor array panel according to an exemplary embodiment of the present invention.

FIG. 2 is a cross-sectional view of the thin film transistor array panel shown in FIG. 1 taken along the lines II-II.

FIG. 3 and FIG. 4 are cross-sectional views showing the thin film transistor array panel in intermediate steps of the manufacturing method of the thin film transistor array panel according to an exemplary embodiment of the present invention.

FIG. 5 is a layout view showing the thin film transistor array panel in intermediate steps of the manufacturing method of the thin film transistor array panel according to an exemplary embodiment of the present invention.

FIG. 6 is a cross-sectional view of the thin film transistor array panel shown in FIG. 5 taken along the lines VI-VI.

FIG. 7, FIG. 8, FIG. 9 and FIG. 10 are cross-sectional views showing the thin film transistor array panel in intermediate steps of the manufacturing method of the thin film transistor array panel according to an exemplary embodiment of the present invention.

FIG. 11 is a layout view of a thin film transistor array panel according to another exemplary embodiment of the present invention.

FIG. 12 is a cross-sectional view of the thin film transistor array panel shown in FIG. 11 taken along the line XII-XII.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element such as a layer, film, region, or substrate is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. It will be understood that when an element such as a layer, film, region, or substrate is referred to as being “under” another element, it may be directly under the other element or intervening elements may be present. In contrast, when an element is referred to as being “directly under” another element, there are no intervening elements present.

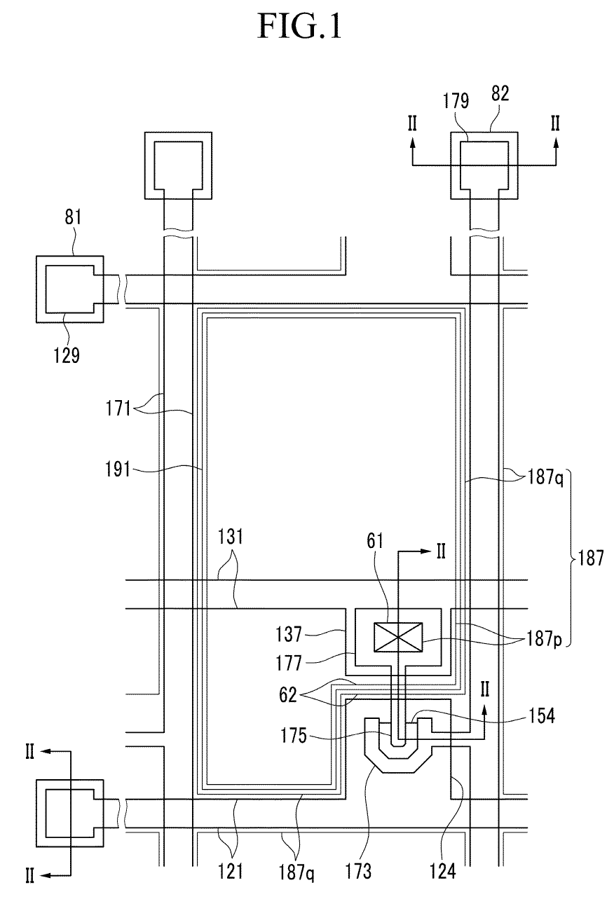

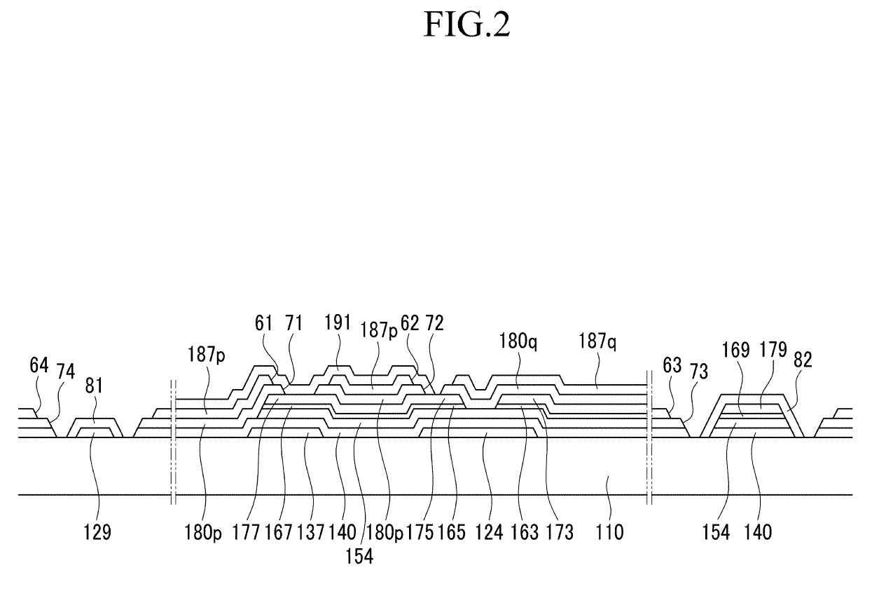

Now, a thin film transistor array panel according to an exemplary embodiment of the present invention will be described with reference to FIG. 1 and FIG. 2.

FIG. 1 is a layout view of a thin film transistor array panel according to an exemplary embodiment of the present invention, and FIG. 2 is a cross-sectional view of the thin film transistor array panel shown in FIG. 1 taken along the lines II-II.

A gate line (121 and 129), a gate electrode 124, a storage electrode line 131, and a storage electrode 137 are formed on an insulating substrate 110, which may be made of glass or plastic. Each gate line 121 transmits a gate signal and extends in an approximate row direction, and includes a plurality of gate electrodes 124 protruding upward and the end portion 129. However, the end portion 129 of the gate line may be omitted.

The storage electrode line 131, which is applied with a predetermined voltage, extends substantially parallel to the gate line 121, and includes the storage electrode 137 with a substantially quadrangular shape. However, in other exemplary embodiments, the storage electrode line 131 and the storage electrode 137 may have various other shapes and/or arrangements. Further, in an exemplary embodiment, the storage electrode line 131 and the storage electrode 137 may be omitted.

The gate line (121 and 129) and the storage electrode line 131 may include an aluminum-based metal of aluminum (Al) or aluminum alloys, a silver-based metal of silver (Ag) or silver alloys, a copper-based metal of copper (Cu) or copper alloys, a molybdenum-based metal of molybdenum (Mo) or molybdenum alloys, chromium (Cr), tantalum (Ta), titanium (Ti), etc. However, one or both of the gate line (121 and 129) and the storage electrode line 131 may have a multi-layered structure including two conductive films (not shown) having different physical characteristics.

A gate insulating layer 140 is formed on the gate lines 121 and the storage electrode lines 131. The gate insulating layer 140 may include silicon nitride (SiNx) or silicon oxide (SiOx).

A semiconductor 154, which may include hydrogenated amorphous silicon (a-Si is an abbreviation for amorphous silicon), polysilicon, or so on, is formed on the gate insulating layer 140.

Ohmic contacts 163, 165, 167 and 169 are formed on the semiconductor 154. The ohmic contacts 163, 165, 167 and 169 may include a material such as n+ hydrogenated amorphous silicon in which an n-type impurity such as phosphor is doped with a high density, or may include silicide.

A data line (171 and 179) and a drain electrode 175 are formed on the ohmic contacts 163, 165, 167 and 169. The data line 171 transmits a data voltage and extends in an approximate column direction, thereby crossing the gate line 121. The data line 171 includes an end portion 179, and a source electrode 173 curved in a “U” shape on the gate electrode 124.

The drain electrode 175 is separated from the data line 171, and includes a narrow portion and a wide portion 177. The narrow portion includes an end portion enclosed by the source electrode 173, and the wide portion 177 is almost quadrangular and overlaps the storage electrode 137. The wide portion 177 of the drain electrode 175 has almost the same area as the storage electrode 137.

The data line 171 and 179, and the drain electrode 175 and 177 may include a refractory metal such as molybdenum, chromium, tantalum, and titanium, or alloys thereof, and may have a multilayer structure including the refractory metal layer (not shown) and a low resistance conductive layer (not shown).

The gate electrode 124, the source electrode 173, and the drain electrode 175 form a thin film transistor (TFT) along with the semiconductor 154, and the channel of the thin film transistor is formed in the semiconductor 154 between the source electrode 173 and the drain electrode 175. The drain electrode 175 is connected to a pixel electrode 191 of the liquid crystal display, and thereby applies a driving voltage.

The semiconductor 154, the ohmic contacts 163, 165, 167 and 169, the data line (171 and 179), and the drain electrode (175 and 177) have substantially the same plane shape. This is because three layers respectively including the semiconductor 154, the ohmic contacts 163, 165, 167 and 169, the data line (171 and 179), and the drain electrode 177 are sequentially deposited and patterned by using one mask. However, the portion of the semiconductor 154 that provides the channel of the thin film transistor is not covered by the ohmic contacts 163, 165, 167 and 169, or the data line (171 and 179).

A passivation layer 180, which may include a material such as silicon nitride (SiNx) or silicon oxide (SiOx), is formed on the data line (171 and 179) and the drain electrode 175. The passivation layer 180 has a first passivation layer opening 71, a second passivation layer opening 72, a third passivation layer opening 73, and a fourth passivation layer opening 74. Also, the passivation layer 180 includes a first passivation layer pattern 180p and a second passivation layer pattern 180q that are separated from each other. Here, a gap between the first passivation layer pattern 180p and the second passivation layer pattern 180q approximately accords with the second passivation layer opening 72.

The first passivation layer pattern 180p is an island type that is similar to a region occupied with the pixel electrode 191. The first passivation layer pattern 180p has the first passivation layer opening 71 exposing a portion of the expansion 177 of the drain electrode 175. The second passivation layer pattern 180q has a shape that is similar to a region occupied with the gate line 121, the gate electrode 124, and the data line 171. Accordingly, the second passivation layer pattern 180q does not overlap the pixel electrode 191.

The first passivation layer opening 71 exposes the portion of the expansion 177 of the drain electrode 175. The boundary of the first passivation layer opening 71 is disposed inside the boundary of the expansion 177 of the drain electrode 175. The shape of the first passivation layer opening 71 is substantially square, however in other exemplary embodiments, the first passivation layer opening 71 may have various other shapes.

The boundary of the second passivation layer opening 72 is aligned with the boundary of the pixel electrode 191. The shape of the second passivation layer opening 72 is an approximate donut shape. The second passivation layer opening 72 exposes a portion of the drain electrode 175. Furthermore, the second passivation layer opening 72 may expose a portion of the gate insulating layer 140, the substrate 110, or both.

The third passivation layer opening 73 exposes at least a portion of the end portion 179 of the data line 171. Furthermore, the third passivation layer opening 73 may expose a portion of the gate insulating layer 140, the substrate 110, or both. The third passivation layer opening 73 has an approximate square shape, however in other exemplary embodiments, the third passivation layer opening 73 may have various other shapes.

The fourth passivation layer opening 74 exposes at least a portion of the end portion 129 of the gate line 121. Furthermore, the fourth passivation layer opening 74 may expose the portion of the gate insulating layer 140, the substrate 110, or both. The fourth passivation layer opening 74 has an approximate square shape, however in other exemplary embodiments, the fourth passivation layer opening 74 may have various other shapes.

An upper layer 187 is formed on the passivation layer 180. The upper layer 187 may include a metal oxide semiconductor (MOS) such as indium gallium zinc oxide (InGaZnO: IGZO). The upper layer 187 includes a first upper layer opening 61, a second upper layer opening 62, a third upper layer opening 63, and a fourth upper layer opening 64. The upper layer 187 includes a first upper layer pattern 187p and a second upper layer pattern 187q that are separated from each other. Here, a gap between the first upper layer pattern 187p and the second upper layer pattern 187q approximately accords with the second upper layer opening 62.

The first upper layer pattern 187p has an island shape that is approximately similar to the plane shape of the pixel electrode 191, and the plane size thereof is slightly smaller than the pixel electrode 191. The first upper layer pattern 187p overlaps with the pixel electrode 191. The boundary of the first upper layer pattern 187p is aligned with the boundary of the first passivation layer pattern 180p, and is disposed inside the boundary of the first passivation layer pattern 180p. Here, the width between the boundary of the first upper layer pattern 187p and the boundary of the first passivation layer pattern 180p may be more than about 0.2 μm, and for example may be about 0.75 μm. Accordingly, the plane size of the first upper layer pattern 187p is smaller than the first passivation layer pattern 180p. The first upper layer pattern 187p includes the first upper layer opening 61 exposing a portion of the expansion 177 of the drain electrode 175.

The shape of the second upper layer pattern 187q is approximately similar to the plane shape of the data line 171, the gate line 121, and the gate electrode 124, and the plane size thereof is slightly smaller than the second passivation layer pattern 180q. The second upper layer pattern 187q overlaps the data line 171, the gate line 121, and the gate electrode 124, but it does not overlap the pixel electrode 191. The boundary of the second upper layer pattern 187q is disposed inside the boundary of the second passivation layer pattern 180q. Here, the width between the boundaries may be more than about 0.2 μm, and for example may be about 0.75 μm.

The plane shape of the first upper layer opening 61 is similar to the plane shape of the first passivation layer opening 71, but the plane size of the first upper layer opening 61 is larger than the plane size of the first passivation layer opening 71. The first passivation layer opening 71 is disposed inside the first upper layer opening 61. Accordingly, the first upper layer opening 61 exposes a portion of the first passivation layer pattern 180p around the first passivation layer opening 71. Here, the width of the exposed portion of the first passivation layer pattern 180p is larger than about 0.2 μm, and for example may be about 0.75 μm. The description of the first upper layer opening 61 and the first passivation layer opening 71 may be similarly applied to the description of the second upper layer opening 62 and the second passivation layer opening 72, the third upper layer opening 63 and the third passivation layer opening 73, and the fourth upper layer opening 64 and the fourth passivation layer opening 74.

The pixel electrode 191 is formed on the upper layer 187. The pixel electrode 191 may include a transparent conductive oxide such as indium tin oxide (ITO) and indium zinc oxide (IZO). The pixel electrode 191 does not overlap the gate line 121, the gate electrode 124, and the data line 171.

Connecting members 81 and 82 are respectively disposed on the end portions 129 and 179 of the gate line 121 and the data line 171. The connecting members 81 and 82 may include the same material as the pixel electrode 191.

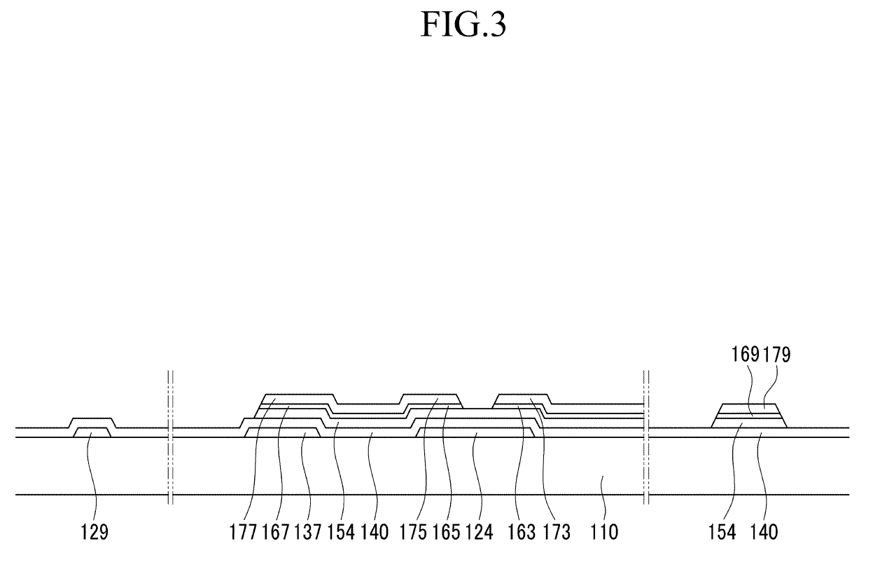

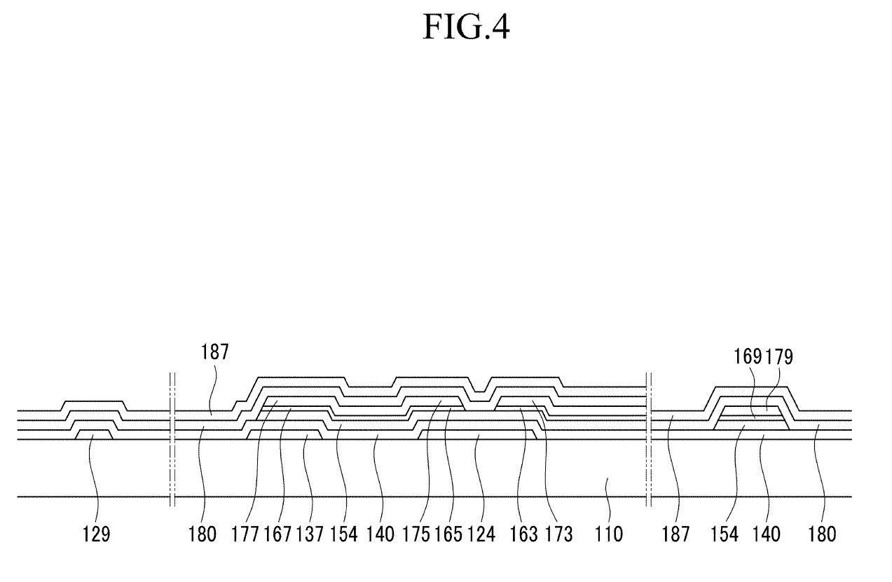

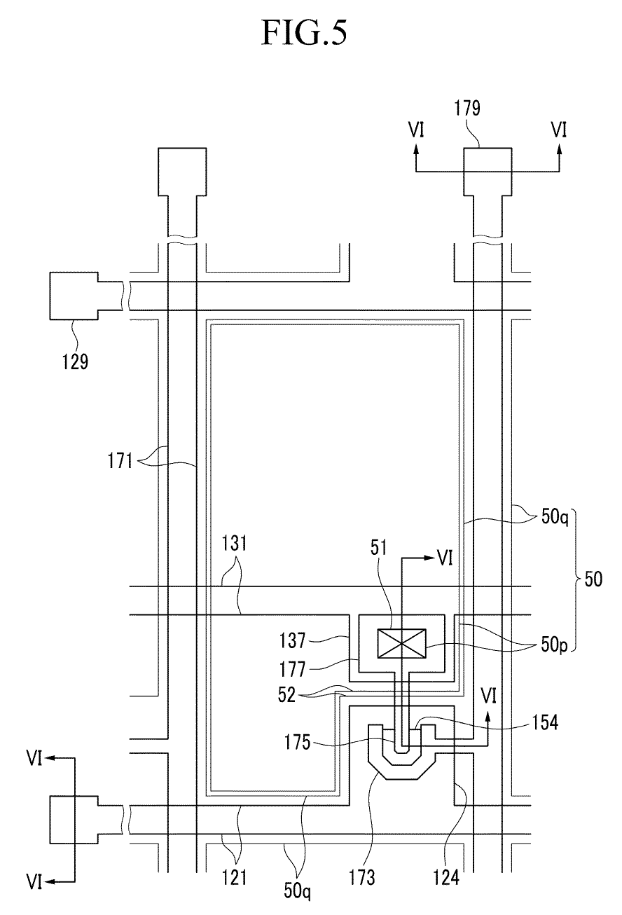

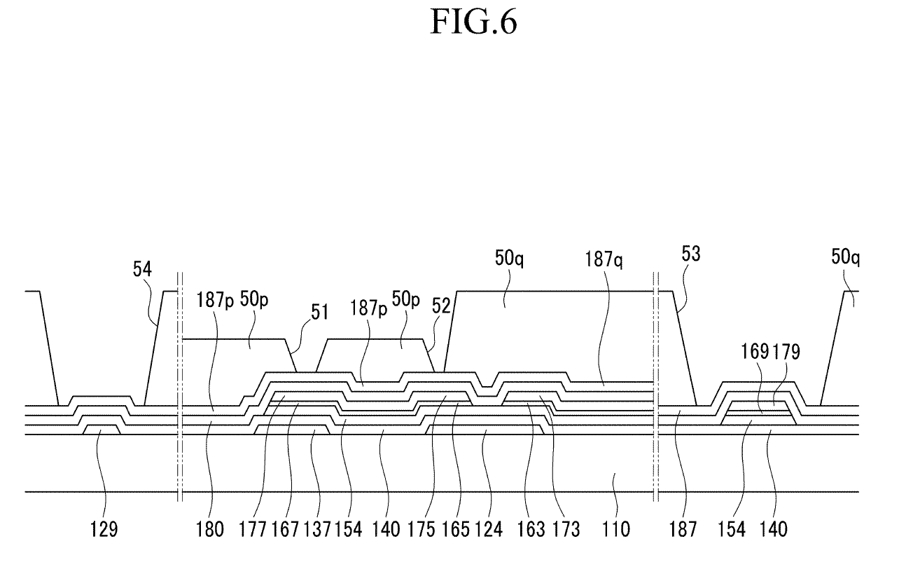

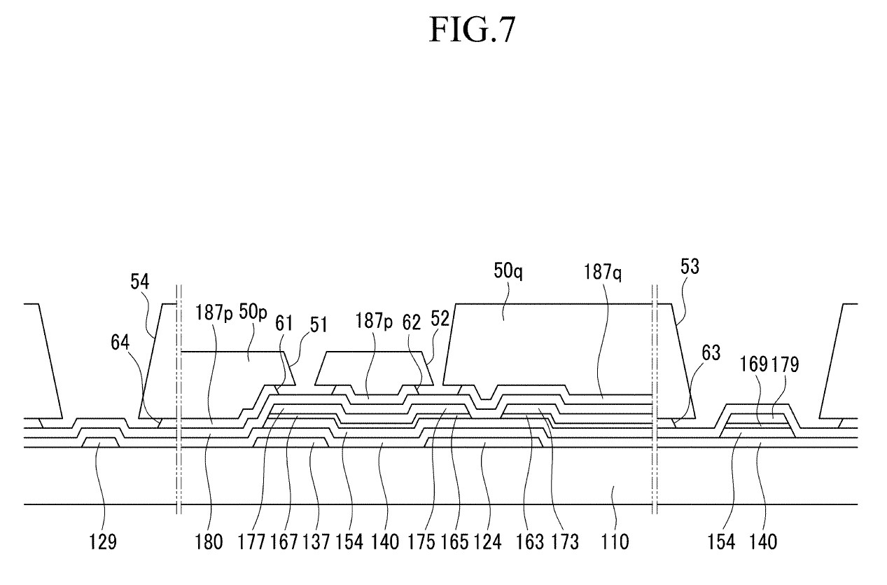

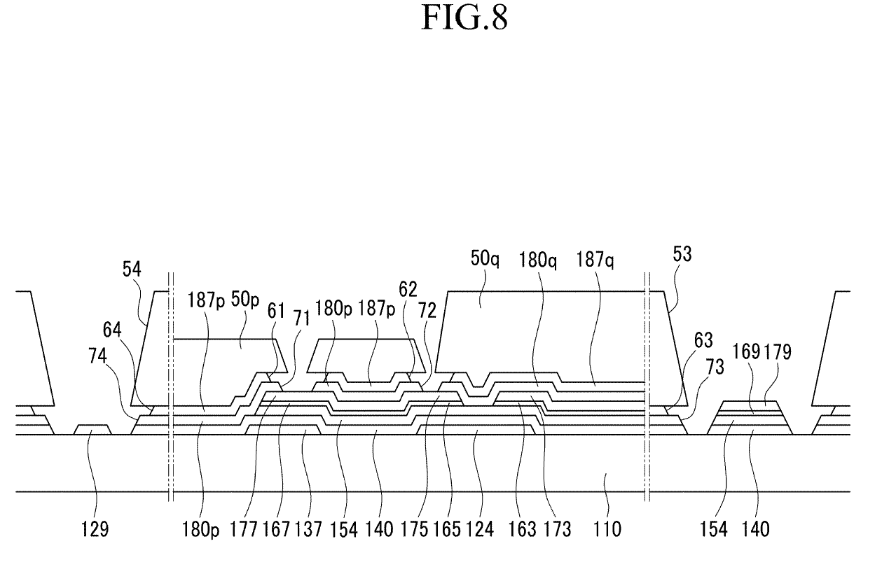

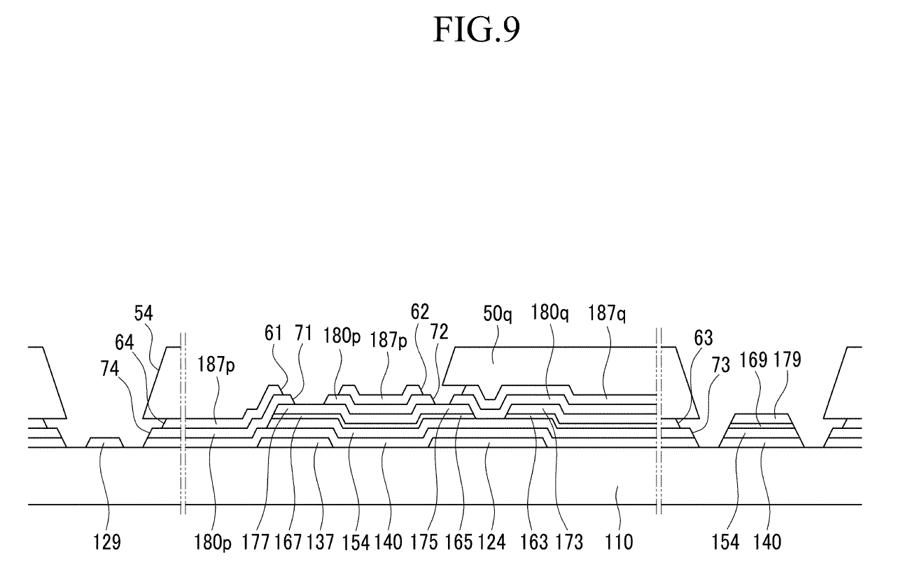

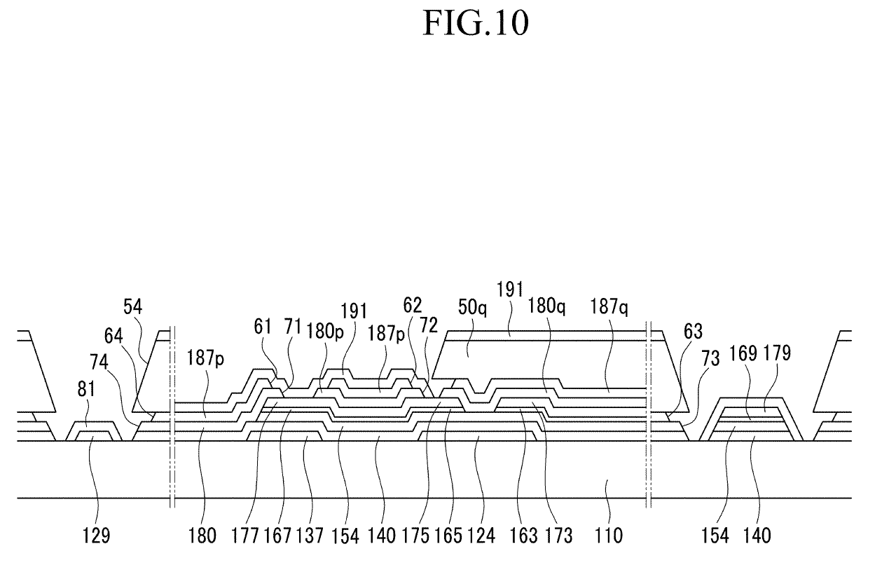

Next, a manufacturing method of a thin film transistor array panel according to an exemplary embodiment of the present invention will be described with reference to FIG. 3, FIG. 4, FIG. 5, FIG. 6, FIG. 7, FIG. 8, FIG. 9, and FIG. 10. Here, further detailed description overlapping with the description of the thin film transistor array panel of FIG. 1 and FIG. 2 is omitted.

FIG. 3 and FIG. 4 are cross-sectional views showing the thin film transistor array panel in intermediate steps of the manufacturing method of the thin film transistor array panel according to an exemplary embodiment of the present invention.

A gate line (121 and 129), a gate electrode 124, a storage electrode line 131, and a storage electrode 137 are formed on the substrate 110.

Next, a gate insulating layer 140 is formed on the gate line 121 and the storage electrode line 131.

Next, as shown in FIG. 3, a semiconductor 154, ohmic contacts 163, 165, 167 and 169, and a data line (171 and 179) and a drain electrode (175 and 177) are sequentially deposited on the entire surface of the gate insulating layer 140, and are patterned through a photolithography process.

Next, as shown in FIG. 4, a passivation layer 180 and an upper layer 187 are sequentially deposited on the whole surface of the panel.

FIG. 5 is a layout view showing the thin film transistor array panel in intermediate steps of the manufacturing method of the thin film transistor array panel according to an exemplary embodiment of the present invention, and FIG. 6 is a cross-sectional view of the thin film transistor array panel shown in FIG. 5 taken along the lines VI-VI.

A photosensitive film 50 is coated on the upper layer 187, and exposed and developed through a photo process using a mask to form a first photosensitive film pattern 50q and a second photosensitive film pattern 50p.

The photosensitive film 50 has different thicknesses depending on positions, and particularly includes the first photosensitive film pattern 50q and the second photosensitive film pattern 50p. The first photosensitive film pattern 50q is thicker than the second photosensitive film pattern 50p. The first photosensitive film pattern 50q covers the whole region occupied with the gate line 121, the gate electrode 124, and the data line 171. The second photosensitive film pattern 50p is formed on the region where a pixel electrode 191 will be disposed except for a portion of the expansion 177 of the drain electrode 175. The plane shape of the second photosensitive film pattern 50p is similar to the plane shape of the pixel electrode 191. The plane of the second photosensitive film pattern 50p may be disposed inside the plane of the pixel electrode 191, or may be equal to or larger than the plane of the pixel electrode 191.

A first photosensitive film opening 51 has a similar plane shape to the first passivation layer opening 71, but has a smaller plane size than the first passivation layer opening 71. The description of the first photosensitive film opening 51 and the first passivation layer opening 71 may be similarly applied to the description for a second photosensitive film opening 52 and the second passivation layer opening 72, a third photosensitive film opening 53 and the third passivation layer opening 73, and a fourth photosensitive film opening 54 and the fourth passivation layer opening 74.

There are many methods of forming the different thicknesses according to location of the photosensitive film. One example of the methods includes forming a photomask with a translucent area as well as a light transmitting area and a light blocking area. The translucent area may be provided with a slit pattern, a lattice pattern, or a thin film having medium transmittance or thickness. In the case of utilizing the slit pattern, it is preferable that the slit width or the space between the slits is smaller than the resolution of exposure equipment used in the photolithography process. Another example of the method includes using a reflowable photosensitive film. That is, the method forms a thin portion by making a photosensitive film flow into a region where the photosensitive film is not present after forming the reflowable photosensitive film with a general exposure mask having only a light transmitting area and a light blocking area.

FIG. 7, FIG. 8, FIG. 9, and FIG. 10 are cross-sectional views showing the thin film transistor array panel in intermediate steps of the manufacturing method of the thin film transistor array panel according to an exemplary embodiment of the present invention.

The upper layer 187 is wet-etched to form the first upper layer opening 61, the second upper layer opening 62, the third upper layer opening 63, and the fourth upper layer opening 64. Here, the upper layer 187 is considerably undercut inside the boundary of the photosensitive film patterns 50p and 50q. The undercut may be formed to be more than about 0.2 μm, and for example may be about 0.75 μm. On the other hand, the etch speed of the metal layer is about 800-3500 Å/min according to the kinds thereof, and the etch speed of the metal oxide semiconductor is about 3800-4400 Å/min. Accordingly, the upper layer 187 having the faster etch speed may be considerably more undercut than the metal layer such that a lift off process that will be executed later may be more efficiency performed. Also, when using the upper layer 187, transmittance deterioration may be prevented. However, when using the metal layer in substitution for the upper layer 187, a metal layer material remains after the etching such that the transmittance may be deteriorated.

Next, the passivation layer 180 is dry-etched to form the first passivation layer opening 71, the second passivation layer opening 72, the third passivation layer opening 73, and the fourth passivation layer opening 74. On the other hand, when using an upper passivation layer rather than the upper layer 187, the underlying passivation layer 180 may be damaged when wet-etching the upper passivation layer.

Next, referring to FIG. 9, an etch-back process is executed such that the photosensitive film 50 is wholly etched with a uniform thickness. Here, the second photosensitive film pattern 50p is completely removed, and the first photosensitive film pattern 50q is thinned.

Next, referring to FIG. 10, a pixel electrode 191 and connecting members 81 and 82 including ITO or IZO are formed on the whole surface of the panel.

Next, the first photosensitive film pattern 50q is removed, and this process is referred to as a lift-off process. Here, the etchant may be the same as the etchant used to form the data line 171.

As a result, when a considerable undercut is formed under a periphery of the first photosensitive film pattern 50q, it is easy for the first photosensitive film pattern 50q to be removed.

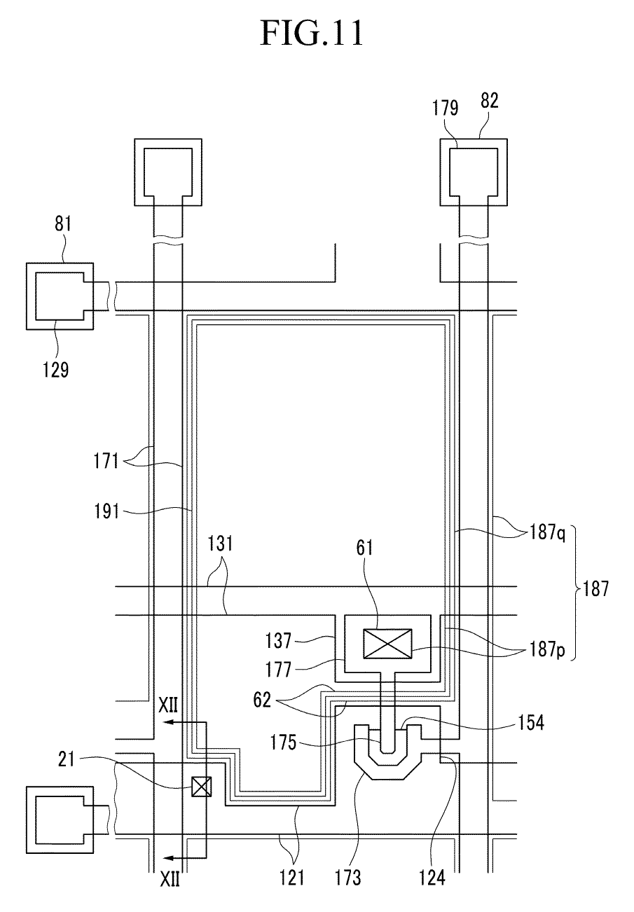

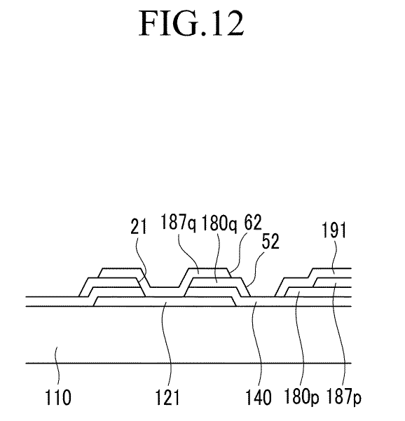

Next, a thin film transistor array panel according to another exemplary embodiment of the present invention will be described with reference to FIG. 11 and FIG. 12. Here, further detailed description overlapping with that of the thin film transistor array panel shown in FIG. 1 to FIG. 2 is omitted.

FIG. 11 is a layout view of a thin film transistor array panel according to another exemplary embodiment of the present invention, and FIG. 12 is a cross-sectional view of the thin film transistor array panel shown in FIG. 11 taken along the line XII-XII.

Differently from the thin film transistor array panel of FIG. 1 to FIG. 2, the gate line 121 is electrically connected to the second upper layer pattern 187q through a contact hole 21. The upper layer 187 may include the transparent conductive oxide. Here, the transparent conductive oxide may include ITO or IZO. Also, the arrangement, size, and shape of the contact hole 21 may be variously changed.

The gate line 121 and the upper layer 187 are connected to each other through the contact hole 21 such that the gate electrode 124 and the second upper layer pattern 187q are applied with the same voltage, thereby forming a double gate structure.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A thin film transistor array panel, comprising:
a substrate;
a gate line disposed on the substrate, the gate line comprising a gate electrode;
a gate insulating layer disposed on the gate line;
a semiconductor disposed on the gate insulating layer;
a data line disposed on the semiconductor, the data line comprising a source electrode;
a drain electrode disposed on the semiconductor, the drain electrode facing the source electrode;
a passivation layer disposed on the data line and the drain electrode;
an upper layer disposed on the passivation layer, the upper layer comprising a metal oxide semiconductor or a transparent conductive oxide; and
a pixel electrode disposed on the upper layer, the pixel electrode connected to the drain electrode,
wherein the upper layer comprises a first upper layer pattern overlapping with the pixel electrode.

2. The thin film transistor array panel of claim 1, wherein
the boundary of the first upper layer pattern is aligned with the boundary of the pixel electrode inside the boundary of the pixel electrode.

3. The thin film transistor array panel of claim 2, wherein
the first upper layer pattern comprises a first upper layer opening exposing a portion of the drain electrode.

4. The thin film transistor array panel of claim 3, wherein
the passivation layer comprises a first passivation layer pattern overlapping with the first upper layer pattern.

5. The thin film transistor array panel of claim 4, wherein
the boundary of the first passivation layer pattern is aligned with the boundary of the first upper layer pattern outside the boundary of the first upper layer pattern.

6. The thin film transistor array panel of claim 5, wherein
the width between the boundary of the first passivation layer pattern and the boundary of the first upper layer pattern is more than about 0.2 μm.

7. The thin film transistor array panel of claim 1, wherein
the upper layer comprises a second upper layer pattern, and
the second upper layer pattern overlaps the gate line, the gate electrode, and the data line, and is separated from the first upper layer pattern.

8. The thin film transistor array panel of claim 7, wherein
the boundary of the second upper layer pattern is aligned with the boundary of a region occupied with the gate line, the gate electrode, and the data line outside the boundary of the region.

9. The thin film transistor array panel of claim 8, wherein
the passivation layer comprises a second passivation layer pattern overlapping with the second upper layer pattern.

10. The thin film transistor array panel of claim 9, wherein
the boundary of the second passivation layer pattern is aligned with the boundary of the second upper layer pattern outside the boundary of the second upper layer pattern.

11. The thin film transistor array panel of claim 10, wherein
the width between the boundary of the second passivation layer pattern and the boundary of the second upper layer pattern is more than about 0.2 μm.

12. The thin film transistor array panel of claim 1, wherein
the data line comprises an end portion, the upper layer comprises a third upper layer opening, and the end portion of the data line is disposed inside the third upper layer opening.

13. The thin film transistor array panel of claim 12, wherein
the semiconductor comprises an end portion, and the end portion of the semiconductor has substantially the same plane shape as the end portion of the data line.

14. The thin film transistor array panel of claim 1, wherein
the gate line comprises an end portion, the upper layer comprises a fourth upper layer opening, and the end portion of the gate line is disposed inside the fourth upper layer opening.

15. The thin film transistor array panel of claim 1, wherein
the gate line is connected to the upper layer through a contact hole.

16. A method for manufacturing a thin film transistor array panel, comprising:
forming a gate line on a substrate, the gate line comprising a gate electrode;
forming a gate insulating layer on the gate line;
forming a semiconductor on the gate insulating layer;
forming a data line on the semiconductor;
simultaneously patterning the semiconductor and the data line;
forming a passivation layer on the data line;
forming an upper layer on the passivation layer;
forming a photosensitive film pattern on the upper layer;
etching the upper layer using the photosensitive film pattern as a mask;
etching the passivation layer; and
forming a pixel electrode on the passivation layer,
wherein the upper layer comprises a metal oxide semiconductor or a transparent conductive oxide, and comprises a first upper layer pattern overlapping with the pixel electrode.

17. The method of claim 16, wherein
the photosensitive film pattern comprises a first photosensitive film pattern and a second photosensitive film pattern, and
the first photosensitive film pattern and the second photosensitive film pattern have different thicknesses from each other and are spaced apart from each other.

18. The method of claim 17, wherein
the etching of the upper layer comprises forming the first upper layer pattern inside the boundary of the first photosensitive film pattern.

19. The method of claim 18, wherein
the etching of the passivation layer comprises forming a first passivation layer pattern outside the boundary of the first upper layer pattern.

20. The method of claim 17, wherein
the second photosensitive film pattern covers a region occupied with the gate line, the gate electrode, and the data line.

21. The method of claim 20, wherein
the etching of the upper layer comprises forming a second upper layer pattern inside the boundary of the second photosensitive film pattern.

22. The method of claim 21, wherein
the etching of the passivation layer comprises forming a second passivation layer pattern outside the boundary of the second upper layer pattern.
